(19) United States
(12) Patent Application Publication
(10) Pub. No.: US 2009/0159003 A1
(43) Pub. Date: Jun. 25, 2009

(54) DEVICE FOR SUPPLYING ORGANIC METAL COMPOUND

(75) Inventors: Hideki Noguchi, Ube (JP); Kouji Ishiji, Ube (JP); Tooru Hiratsuka, Ube (JP); Hirotaka Yakushijin, Ube (JP); Kenji Matsushige, Ube (JP); Susumu Yoshitomi, Ube (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES LTD, UBE (JP)

(21) Appl. No.: 12/302,796

(22) PCT Filed: May 30, 2007
(86) PCT No.: PCT/JP2007/061005

§ 371 Date: Jan. 9, 2009

(30) Foreign Application Priority Data
May 30, 2006 (JP) 2006-149395
Dec. 28, 2006 (JP) 2006-353879
Dec. 28, 2006 (JP) 2006-353880
Dec. 28, 2006 (JP) 2006-353881
Apr. 12, 2007 (JP) 2007-104886

(51) Int. Cl. C23C 16/44

(52) U.S. Cl. 118/715

(57) ABSTRACT

A supplying device has two columnar containers 1, 1′ and communicating tube 5 for connecting the insides of containers 1, 1′ with each other at the lower ends. Containers 1, 1′ are filled with an organic metal compound which is in a solid state at room temperature. The upper portion of container 1 is equipped with gas feed tube 2 for introducing a carrier gas into container 1. The upper portion of container 1′ is equipped with gas discharge tube 3 for discharging the carrier gas containing the organic metal compound.

### TECHNICAL FIELD

The present invention relates to a device for supplying an organic metal compound along with a carrier gas by allowing the carrier gas to flow in a container filled with the organic metal compound which is in a solid state at room temperature.

### BACKGROUND ART

In the production of compound semiconductor devices, a MOCVD process (Metal Organic Chemical Vapor Deposition process) has been generally used. In this process, it is important to stably gasify an organic metal compound which is in a solid state at room temperature and supply the gasified organic metal compound.

In the past, as a supplying device for gasifying an organic metal compound which is in a solid state at room temperature and supplying the gasified organic metal compound, there has been known a supplying device disclosed in Patent Document 1. The supplying device disclosed in Patent Document 1 has a container filled with an organic metal compound, a tube for introducing a carrier gas inserted into the container from the upper portion of the container and a disperser positioned at the lower portion of the tube. The upper portion of the container is equipped with an outlet for an organic compound gas and a carrier gas, while the lower portion of the container is provided with a reduced diameter portion having a reduced inner diameter as compared to the upper portion.

However, since the inside of the container is filled with an organic metal compound which is in a solid state at room temperature, there is still a problem such that the organic metal compound and the carrier gas in the container are not fully in contact with each other, and a flow path for letting the carrier gas to pass through is formed. Accordingly, the proportion of the organic metal compound remained in the container without being conveyed by the carrier gas is high. So, there has not yet been developed a satisfactory device for stably supplying an organic metal compound over a long period of time.

Patent Document 1: Japanese Examined Patent Publication No. H05-10320

### DISCLOSURE OF THE INVENTION

An object of the present invention is to provide an industrially suitable device for supplying an organic metal compound capable of stably supplying the organic metal compound which is in a solid state at room temperature over a long period of time.

The object of the present invention can be solved by a device for supplying an organic metal compound having a first columnar container and a second columnar container filled with an organic metal compound which is in a solid state at room temperature, and a connecting member for connecting the insides of the first and second containers with each other at the lower ends, wherein the upper portion of the first container is equipped with an inlet of a carrier gas and the upper portion of the second container is equipped with an outlet of the carrier gas containing the organic metal compound.

The inlet may be equipped with a gas feed tube mounted on the first container such that the carrier gas introduced into the first container is allowed to collide against the upper wall surface of the first container. In this case, the tip end of the gas feed tube is preferably directed upward in the inside of the first container.

Alternatively, the inlet may be equipped with a disperser for dispersing the carrier gas introduced into the first container. In this case, the disperser may have a baffle plate for dispersing the carrier gas introduced into the first container by allowing the carrier gas to collide therewith, a perforated pipe positioned in the inside of the first container, or a filter positioned in the inside of the first container.

In the device for supplying an organic metal compound of the present invention, it is preferable that the first container and the second container are positioned such that they are spaced from each other. Further, the connecting member may have a communicating tube for connecting the first container and the second container. In this case, the communicating tube can be composed of a single straight pipe or a plurality of straight pipes.

According to the present invention, it is possible to provide an industrially suitable device for supplying an organic metal compound capable of stably supplying the organic metal compound which is in a solid state at room temperature over a long period of time.

### BRIEF DESCRIPTION OF THE DRAWINGS

FIG. 1 is a schematic cross-sectional view of the device for supplying an organic metal compound according to the first embodiment of the present invention.

FIG. 2 is a schematic cross-sectional view of one modified example of the supplying device illustrated in FIG. 1.

FIG. 3 is a schematic cross-sectional view of another modified example of the supplying device illustrated in FIG. 1.

FIG. 4 is a schematic cross-sectional view of the device for supplying an organic metal compound according to the second embodiment of the present invention.

FIG. 5 is a schematic cross-sectional view of the device for supplying an organic metal compound according to the third embodiment of the present invention.

FIG. 6 is a schematic cross-sectional view of one modified example of the supplying device illustrated in FIG. 5.

FIG. 7 is a schematic cross-sectional view of another modified example of the supplying device illustrated in FIG. 5.

FIG. 8 is a schematic cross-sectional view of another modified example of the supplying device illustrated in FIG. 5.

FIG. 9 is a front view showing an appearance of one concrete example of the supplying device according to the present invention.

FIG. 10 is a rear view of the supplying device illustrated in FIG. 9.

FIG. 11 is a right-side view of the supplying device illustrated in FIG. 9.

FIG. 12 is a left-side view of the supplying device illustrated in FIG. 9.

FIG. 13 is a plan view of the supplying device illustrated in FIG. 9.

FIG. 14 is a bottom view of the supplying device illustrated in FIG. 9.

FIG. 15 is a graph showing the test results of Example 1-1.

FIG. 16 is a graph showing the test results of Example 1-2.

FIG. 17 is a schematic cross-sectional view of the supplying device used in Comparative Examples 1 and 2.

FIG. 18 is a graph showing the test results of Comparative Example 1.

FIG. 19 is a graph showing the test results of Example 2-1.

FIG. 20 is a graph showing the test results of Example 3-1.

### EXPLANATION OF THE REFERENCES

1, 1′ containers
2 gas feed tube
3 gas discharge tube
4 filling port
5 communicating tube
6 disperser

### BEST MODE FOR CARRYING OUT THE INVENTION

### First Embodiment

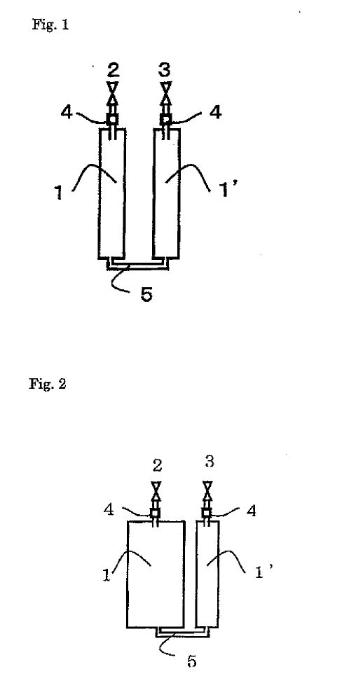

Referring to FIG. 1, the device for supplying an organic metal compound according to the first embodiment of the present invention is illustrated. The supplying device comprises two columnar containers 1, 1′ which are positioned interspatially in parallel to each other and communicating tube 5 for connecting the insides of containers 1, 1′ with each other at the lower ends of containers 1, 1′.

The upper end portion of container 1 on one side is equipped with gas feed tube 2 constituting a gas inlet for introducing a carrier gas into container 1. The upper end portion of container 1′ on the other side is equipped with gas discharge tube 3 constituting a gas outlet for discharging the gas in container 1′ to the outside. In the outside of containers 1, 1′, the middle portion of each of gas feed tube 2 and gas discharge tube 3 is equipped with filling port 4 for filling the insides of containers 1, 1′ with an organic metal compound which is in a solid state at room temperature. Filling ports 4 are constructed such that it can be opened and closed. By opening filling ports 4, the insides of containers 1, 1′ can be filled with the organic metal compound.

The shape of containers 1, 1′ can be any shapes as long as it is columnar, and examples include a cylindrical shape, a triangle tubular shape, a square tubular shape, a hexagonal tubular shape and the like. Of these shapes, containers 1, 1′ in a cylindrical shape are preferably used. The shape of two containers 1, 1′ may be the same or different from each other.

The total capacity of two containers 1, 1′ is not particularly limited, but in consideration of practical use, it is preferably in the range of 10 to 5,000 ml, more preferably in the range of 10 to 3,000 ml and particularly preferably from 25 to 1,000 ml. The capacities of containers 1, 1′ may be the same or different from each other. In case where the capacities of containers 1, 1′ are different from each other, as shown in FIG. 2, the capacity of container 1 into which the carrier gas is introduced, that is, container 1 equipped with gas feed tube 2, is preferably greater than the capacity of container 1′ equipped with gas discharge tube 3. Furthermore, a ratio of the capacity of container 1 equipped with gas feed tube 2 to the capacity of container 1′ equipped with gas discharge tube 3 is preferably from 1 to 80 and more preferably from 1 to 40.

The carrier gas is allowed to flow the insides of containers 1, 1′ mainly in the axial direction of containers 1, 1′. Accordingly, the inner size of containers 1, 1′ has a ratio of the height to the diameter of preferably from 0.8 to 10.0 and more preferably from 1.2 to 10.0 such that the carrier gas flowing in containers 1, 1′ can be effectively brought into contact with the organic metal compound in containers 1, 1′. This is the value assumed when containers 1, 1′ are in a cylindrical shape, but if the containers are not in a cylindrical shape, a circular diameter to be an area equivalent to its cross-sectional area may be obtained from the cross-sectional area.

By having the aspect ratio of containers 1, 1′ within the above range, it is possible to suppress the formation of a gas flow path for letting the carrier gas to pass through without effectively being in contact with the organic metal compound and to maintain the amount of stabilized organic metal compound supplied.

The shape and the construction of communicating tube 5 are not particularly limited as long as it is capable of connecting the insides of two containers 1, 1′ such that the gas can be flowing between the containers. For example, a tube formed in a prescribed shape capable of connecting two containers 1, 1′ at the lower ends by bending a straight pipe, a tube formed by linking a plurality of straight pipes together so as to be in a prescribed shape, and a U-shaped pipe material and the like can be used as communicating tube 5. From the viewpoint of design of communicating tube 5, communicating tube 5 is preferably composed of a straight pipe.

The length of communicating tube 5 is not particularly limited, and can be properly designed depending on the size and the arrangement of two containers 1, 1′. Further, the diameter of communicating tube 5 is not particularly limited as long as the cross-sectional area of communicating tube 5 is small as compared to the cross-sectional area of containers 1, 1′ in the connecting portion with containers 1, 1′.

The shape, the size and the mounting angle with respect to containers 1, 1′ of each of gas feed tube 2 and gas discharge tube 3 are not particularly limited as long as gas feed tube 2 and gas discharge tube 3 are each positioned at the upper end portion of containers 1, 1.

Examples of the organic metal compound which is in a solid state at room temperature used in the present invention include lithium compounds such as tert-butyllithium and the like; organic indium compounds such as trimethylindium, dimethylchloroindium, cyclopontadienylindium, trimethylindium/trimethylarsine adduct, trimethylindium/trimethylphosphine adduct and the like; organic zinc compounds such as ethylzine iodide, ethylcyelopentadienylzinc, cyclopentadienylzine and the like; organic aluminum compounds such as methyldichloroaluminum, triphenylaluminum and the like; organic gallium compounds such as methydichlorogallium, dimethylchlorogallium, dimethylbromogallium and the like; magnesium compounds such as bis(cyclopentadienyl)magnesium and the like; bismuth compounds such as triphenylbismuth and the like; manganese compounds such as bis(cyclopentadienyl)manganese and the like; iron compounds such as ferrocene and the like; barium compounds such as bis(acetylacetonato)barium, barium dipivaloylmethanato/1,10-phenanthroline adduct and the like; strontium compounds such as bis(acetylacetonato)strontium, dipivaloylmethanato strontium and the like; copper compounds such as bis(acetylacetonato)copper, dipivaloylmethanato copper and the like; calcium compounds such as bis(acetylacetonato)calcium, dipivaloylmethanato calcium and the like; and ytterbium compounds such as dipivaloylmethanato ytterbium and the like. Incidentally, the supplying device of the present invention can also be applied to an organic compound free from a metal and an inorganic compound containing a metal or free from a metal, in addition to the organic metal compound, in some cases.

The organic metal compound may be supported on a carrier which is inert to the organic metal compound. As a material of the carrier used in that case, there can be used, for example, alumina, silica, mullite, glassy carbon, graphite, potassium titanate, titanium sponge, quartz, silicon nitride, boron nitride, silicon carbide, stainless steel, aluminum, nickel, titanium, tungsten, fluorine resin, glass and the like. Incidentally these carriers may be used singly, or two or more carriers may be used in combination. Furthermore, the shape of the carrier is not particularly limited, and there can be used, for example, various shapes such as an indeterminate shape, a round shape, an angular shape, a globular shape, a fibrous shape, a reticular shape, a spring shape, a coil shape, a cylindrical shape and the like.

In order to bring into contact the organic metal compound to be supported on the carrier with the carrier gas efficiently, the specific surface area of the carrier is preferably as large as possible. Accordingly, preferably used are a carrier having fine projections and recesses of from about 100 to about 2,000 μm on its surface, and a carrier having a number of pores (voids). Concrete examples of such carriers include alumina ball packing, Raschig rings (made of glass or Teflon (registered trademark)), Heli Pack (made of glass or stainless steel), Dixon packing (made of stainless steel, Fenske (made of glass), titanium sponge, stainless sintered elements, glass wool and the like.

In filling the organic metal compound into a filling apparatus, a known method which is generally carried out can be used. For example, in an inert gas atmosphere, the organic metal compound can be filled in containers 1, 1′ by pouring the organic metal compound directly it is from filling port 4.

The carrier gas introduced into containers 1, 1′ is not particularly limited as long as it is inert to the organic metal compound filled in containers 1, 1′. There can be used, for example, argon, nitrogen, helium, hydrogen and the like. Incidentally, these carrier gases may be used singly, or two or more gases may be used in combination.

The aforementioned supplying device of this embodiment is used by connecting gas feed tube 2 to a carrier gas source and connecting gas discharge tube 3, for example, to a vapor phase epitaxy apparatus in a state that the insides of containers 1, 1′ are filled with the organic metal compound from filling port 4.

The carrier gas is introduced into the supplying device from the carrier gas source in a state that the supplying device is kept at a constant temperature. The introduced carrier gas is supplied to the vapor phase epitaxy apparatus from gas discharge tube 3 through a path of container 1 communicating tube 5 container 1′. The organic metal compound vaporized in containers 1, 1′ is accompanied with flowing of this carrier gas, whereby the vaporized organic metal compound is supplied to the vapor phase epitaxy apparatus from the supplying device along with the carrier gas.

According to the construction of this embodiment, since the carrier gas can be brought into contact with the organic metal compound efficiently and the vaporized organic metal compound can be excellently conveyed with the carrier gas, finally the organic metal compound can be stably supplied over a long period of time.

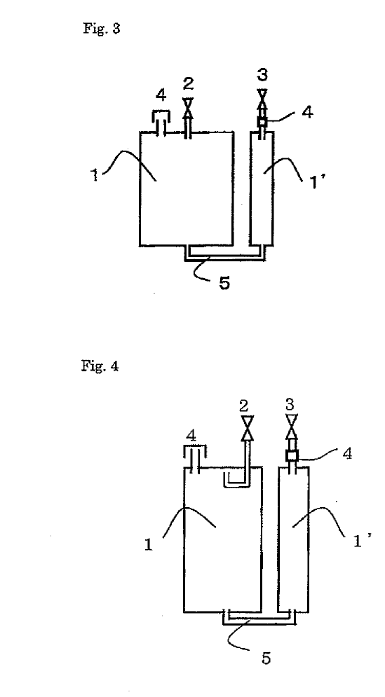

Though, in the above-mentioned embodiment, filling port 4 is equipped in the middle portion of each of gas feed tube 2 and gas discharge tube 3, for example, as shown in FIG. 3, filling port 4 of container 1 can be separately equipped in addition to gas feed tube 2. Though not illustrated, filling port 4 of container 1′ can be separately positioned in addition to gas discharge tube 3, or filling port 4 of both containers 1, 1′ can be separately equipped in addition to gas feed tube 2 and gas discharge tube 3.

### Second Embodiment

FIG. 4 illustrates the device for supplying an organic metal compound according to the second embodiment of the present invention.

In this embodiment, the shape of gas feed tube 2 connected to container 1 is different from that of the first embodiment. More specifically, gas feed tube 2 is bent in the inside of container 1 such that the carrier gas introduced into container 1 is allowed to collide at least against the upper wall surface of the upper wall surface and the side wall surface of the inside of container 1, and a nozzle, i.e., its tip end, is directed upward. Since the other construction may be the same as the first embodiment, the detailed description will be omitted.

By configuring gas feed tube 2 in such a way, the carrier gas right after introduced into container 1 from gas feed tube 2 is allowed to collide against the upper wall surface of the inside of container 1. The carrier gas is allowed to collide against the upper wall surface, whereby the introduced carrier gas is dispersed in the inside of entire container 1 and flowing of the carrier gas can be made in the inside of entire container 1. As a result, the carrier gas containing the organic metal compound can be more stably supplied.

In the embodiment shown in FIG. 4, the tip end portion of gas feed tube 2 is bent such that the carrier gas is introduced substantially perpendicular to the upper wall surface of container 1, but the introduction angle of the carrier gas into container 1 is not particularly limited as long as the carrier gas introduced into container 1 is allowed to collide at least against the upper wall surface of the upper wall surface and the side wall surface of the inside of container 1.

Furthermore, in the embodiment shown in FIG. 4, filling port 4 of container 1 is separately constructed in addition to gas feed tube 2, and the capacities of two containers 1, 1′ are different. However, filling port 4 of container 1 may be equipped in the middle portion of gas feed tube 2, and the capacities of two containers 1, 1′ may be the same. Furthermore, filling port 4 of container 1′ may be separately constructed in addition to gas discharge tube 3.

### Third Embodiment

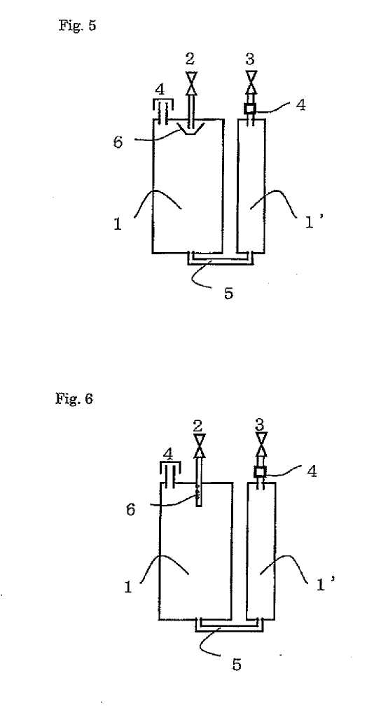

The device for supplying an organic metal compound according to the third embodiment of the present invention is illustrated in FIGS. 5 to 8.

In this embodiment, the supplying device is equipped with disperser 6 for dispersing the carrier gas in the inside of container 1 into which the carrier gas is introduced. The structure and the material of disperser 6 are not limited as long as disperser 6 is positioned in the inside of container 1 and the introduced gas can be dispersed in container 1. Further, the size of disperser 6 is properly selected depending on the shape and the size of container 1, the amount of the carrier gas to be introduced, the size of gas feed tube 2 and the like. As disperser 6, there can be used, for example, a filter made of a sintered metal, glass or the like, a net, a honeycomb, a baffle plate, a perforated pipe and the like. A sintered metal-made filter, a baffle plate and a perforated pipe can be preferably used, and a baffle plate and a perforated pipe can be more preferably used.

When a baffle plate is used as disperser 6, the baffle plate is preferably positioned in parallel to the upper wall surface of container 1 in order to disperse the carrier gas introduced into container 1 well in container 1. When a perforated pipe is used as disperser 6, the perforated pipe is preferably positioned such that holes formed at the perforated pipe are faced to the direction perpendicular to the upper wall surface of container 1 in order to introduce the carrier gas into container 1 to disperse well therein.

In the supplying device illustrated in FIG. 5, disperser 6 has a baffle plate formed in a cone shape with a recessed part in the center. The baffle plate is positioned in parallel to the upper wall surface of container 1 at the lower part of gas feed tube 2 such that the recessed part faces a nozzle of gas feed tube 2. The carrier gas introduced into container 1 from gas feed tube 2 is allowed to collide against the baffle plate, whereby the carrier gas right after introduced into container 1 is dispersed in container 1.

In the supplying device illustrated in FIG. 6, disperser 6 is composed of a perforated pipe obtained by forming a plurality of holes in its peripheral surface, while the perforated pipe is positioned such that the peripheral surface is perpendicular to the upper wall surface of container 1. According to this, holes formed in the perforated pipe are faced to the direction perpendicular to the upper wall surface of container 1.

The number and the size of the holes formed in the perforated pipe are not particularly limited. Furthermore, the position of the holes is not particularly limited either, but holes are preferably formed over the entire periphery of the pipe in order to more uniformly disperse the carrier gas in container 1. Disperser 6 composed of a perforated pipe opens a plurality of holes in the peripheral surface of gas feed tube 2, whereby it can be constructed as a part of gas feed tube 2. Alternatively, disperser 6 composed of a perforated pipe may be composed of a member different from that of gas feed tube 2. The carrier gas passes through disperser 6 that is a perforated pipe from gas feed tube 2 and is dispersed in container 1 from holes formed in its peripheral surface and introduced thereinto.

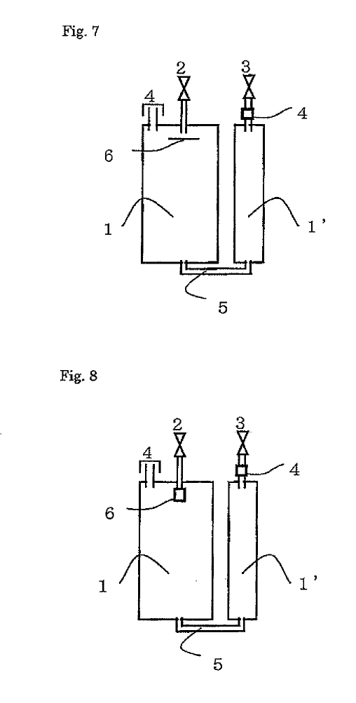

The supplying device illustrated in FIG. 7, disperser 6 has a baffle plate comprising a flat plate. The baffle plate is positioned in parallel to the upper wall surface of container 1 at the lower part of gas feed tube 2 such that the plate faces gas feed tube 2. The carrier gas introduced into container 1 from the gas feed tube is allowed to collide against this baffle plate, whereby the carrier gas right after introduced into container 1 is dispersed in container 1.

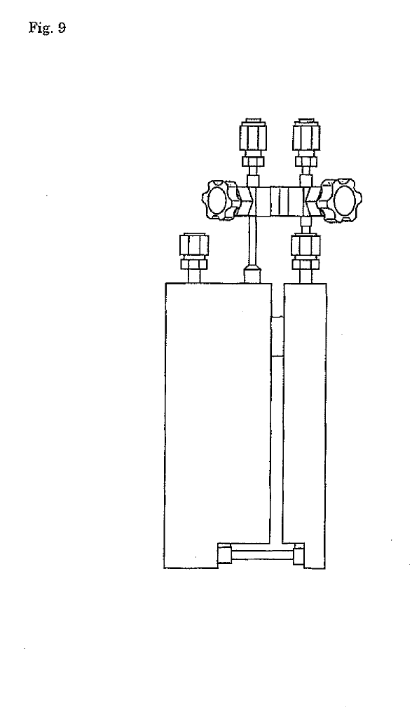

The supplying device illustrated in FIG. 8, disperser 6 has a filter mounted on the lower end of gas feed tube 2. The carrier gas is introduced into container 1 through the filter and allowed to pass through fine pores of the filter, whereby the carrier gas is introduced into container 1 to disperse therein.

In FIGS. 5 to 8, filling port 4 of container 1 may be positioned in the middle portion of gas feed tube 2, and the capacities of two containers 1, 1′ may be the same. Furthermore, filling port 4 of container 1′ may be separately constructed in addition to gas discharge tube 3.

As described above, the present invention is illustrated by means of the first to third embodiments, but the present invention is not restricted to the aforementioned embodiments and can be subjected to various modifications within the scope of technical ideas of the present invention.

For example, in the aforementioned embodiments, two containers 1, 1′ are positioned such that they are spaced from each other, but the containers may be positioned in contact with each other. Also, in the aforementioned embodiments, two containers 1, 1′ are positioned in parallel, but mutual positional relation is not particularly limited as long as the lower ends of two containers 1, 1′ are connected to each other.

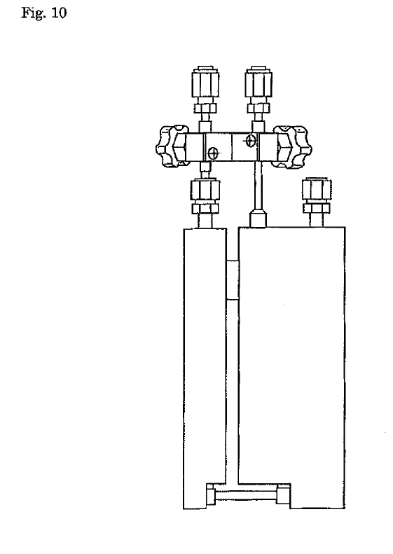

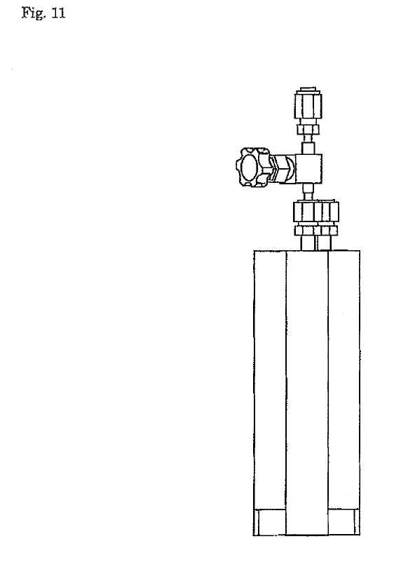

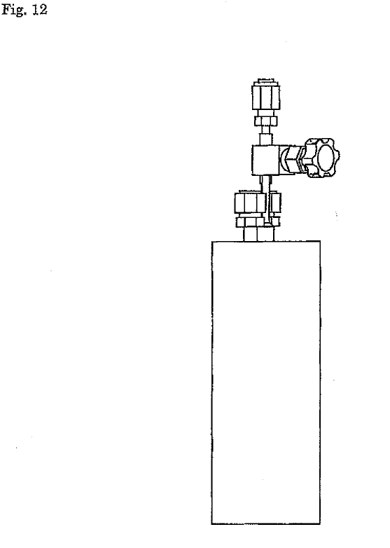

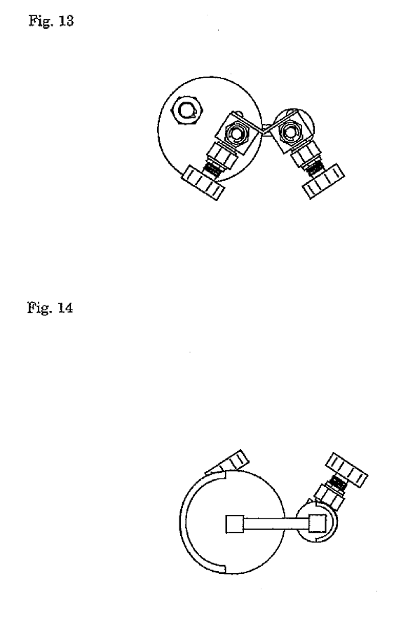

In FIGS. 9 to 14, the appearance of one example of the supplying device formed according to the present invention will be illustrated in detail. FIG. 9 is a front view, FIG. 10 is its rear view, FIG. 11 is its right-side view, FIG. 12 is its left-side view, FIG. 13 is its plan view, and FIG. 14 is its bottom view. The supplying device illustrated in FIGS. 9 to 14 has two containers in a cylindrical shape, and the capacity of a container into which a carrier gas is introduced is greater than that of a container from which the carrier gas is discharged. In the container into which the carrier gas is introduced, a filling port is separately equipped in addition to a gas feed tube. The insides of two containers are connected by a communicating tube linked to the lower ends of the containers. The communicating tube may be composed in combination with a straight pipe.

### EXAMPLES

The present invention is now illustrated in detail below with reference to Examples. However, the scope of the present invention is not restricted to these Examples. The concentration of trimethylindium flowing out from gas discharge tube 3 was measured by means of an ultrasonic type gas concentration meter (product name; Piezocon (a product of Lorex Industries, Inc.)).

1. Direct Introduction

### Example 1-1

### Test on Stability in Supplying Trimethylindium

### Filling Amount; about 25 g

Trimethylindium was prepared as a solid organic metal compound at room temperature, and Heli Pack (stainless steel, 1.3 mm×2.5 mm×2.3 mm (a product of Tokyo Tokushu Kanaami K. K.)) was prepared as a carrier. 38 ml of Hell Pack and 33 g of trimethylindium were put in a TEFLON (registered trademark) container with an inner volume of 250 ml, and the resulting mixture was heated to 90° C. for fully melting trimethylindium and then cooled to room temperature so that trimethylindium was supported on Heli Pack. Subsequently, the resulting material was crushed by means of a spatula and then sifted by means of 4 mesh and 20 mesh sieves to obtain 71 g of trimethylindium supported on Heli Pack having a particle diameter of 0.84 to 4.76 mm.

Two containers 1, 1′ of the supplying device as illustrated in FIG. 1 were filled with 71 g of the resulting trimethylindium supported on Heli Pack having a particle diameter of 0.84 to 4.76 mm from filling port 4 in a nitrogen atmosphere. Each of containers 1, 1′ was in a cylindrical shape of the same size (inner diameter; 17.5 mm, height; 135 mm, inner volume; 31 ml). Communicating tube 5 was composed of a straight pipe having an inner diameter of 4.3 mm. Furthermore, containers 1, 1′ and communicating tube 5 were made of stainless steel.

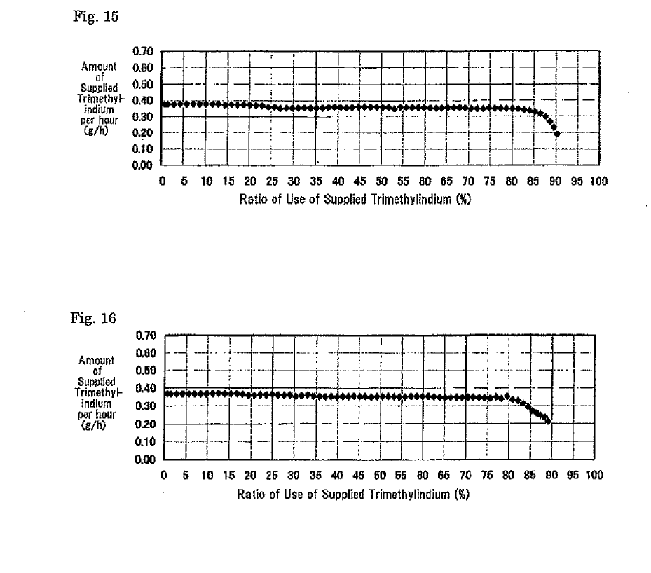

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.38 g per hour, while the supply rate was stable up to 85% of a ratio of use (FIG. 15).

### Example 1-2

### Test on Stability in Supplying Trimethylindium

### Filling Amount; about 25 g

In this Example, as shown in FIG. 3, a stainless-steel supplying device was used, where the volume of container 1 into which a carrier gas was introduced was greater than that of container 1′ from which the carrier gas was discharged, and filling port 4 of container 1 was composed in addition to gas inlet 2. The size of container 1 was an inner diameter of 54 mm, a height of 185 mm and an inner volume of 230 ml. The size of container 1′ was the same as that of container 1′ used in Example 1-1. Further, communicating tube 5 was composed of a straight pipe having an inner diameter of 4.3 mm which was the same as Example 1-1.

This supplying device was filled with 71 g of trimethylindium supported on Heli Pack having a particle diameter of 0.84 to 4.76 mm obtained in the same manner as in Example 1-1 through filling port 4 in a nitrogen atmosphere.

This supplying device was installed in a thermostatic chamber kept at 30° C. and argon gas was allowed to flow at a flow rate of 300 ml per minute as a carrier gas from gas feed tube 2. As a result, the amount of supplied trimethylindium from gas discharge tube 3 was about 0.38 g per hour, while the supply rate was stable up to 80% of a ratio of use (FIG. 16).

### Example 1-3

### Test on Stability in Supplying Trimethylindium

### Filling Amount; about 25 g

In this Example, a stainless steel supplying device (see FIG. 2) composed in the same manner as that used in Example 1-1 was used, except that the size of container 1 into which a carrier gas was introduced was an inner diameter of 37.1 mm, a height of 135 mm and an inner volume of 138 ml. This supplying device was filled with 71 g of trimethylindium supported on Heli Pack having a particle diameter of 0.84 to 4.76 mm obtained in the same manner as in Example 1-1 through filling port 4 in a nitrogen atmosphere.

This supplying device was installed in a thermostatic chamber kept at 30° C. and argon gas was allowed to flow at a flow rate of 300 ml per minute as a carrier gas from gas feed tube 2. As a result, the amount of supplied trimethylindium from gas discharge tube 3 was about 0.40 g per hour, while the supply rate was stable up to 82% of a ratio of use.

### Example 1-4

### Test on Stability in Supplying Trimethylindium

### Filling Amount; about 25 g

In this Example, the same supplying device as that used in Example 1-1 was filled with 75 g of trimethylindium supported on titanium sponge having a particle diameter of 0.84 to 4.76 mm obtained in the same manner as in Example 1-1 through filling port 4 in a nitrogen atmosphere, except that titanium sponge (particle diameter: 0.84 to 2.00 mm (a product of Toho Titanium Co., Ltd.)) was used as a carrier for supporting trimethylindium.

This supplying device was installed in a thermostatic chamber kept at 30° C. and argon gas was allowed to flow at a flow rate of 300 ml per minute as a carrier gas from gas feed tube 2. As a result, the amount of supplied trimethylindium from gas discharge tube 3 was about 0.40 g per hour, while the supply rate was stable up to 87% of a ratio of use.

### Example 1-5

### Test on Stability in Supplying Trimethylindium

### Filling Amount; about 25 g

In this Example, the same supplying device as that used in Example 1-1 was filled with 53 g of trimethylindium supported on Dixon packing having a particle diameter of 0.84 to 4.76 mm obtained in the same manner as in Example 1-1 through filling port 4 in a nitrogen atmosphere, except that Dixon packing (made of stainless steel, φ: 3.0 mm, height: 3.0 mm (a product of Okutani Wire Netting Mfg, Co., Ltd.)) was used as a carrier for supporting trimethylindium.

This supplying device was installed in a thermostatic chamber kept at 30° C. and argon gas was allowed to flow at a flow rate of 300 ml per minute as a carrier gas from gas feed tube 2. As a result, the amount of supplied trimethylindium from gas discharge tube 3 was about 0.40 g per hour, while the supply rate was stable up to 84% of a ratio of use.

### Example 1-6

### Test on Stability in Supplying Trimethylindium

### Filling Amount; about 50 g

In this Example, the supplying device was filled with 152 g of trimethylindium supported on titanium sponge having a particle diameter of 0.84 to 4.75 mm in the same manner as in Example 1-4, except that the supplying device used in Example 1-2 was used as a supplying device, and the test on the stability in supplying trimethylindium was carried out. As a result, the amount of trimethylindium supplied was about 0.40 g per hour, while the supply rate was stable up to 85% of a ratio of use.

### Example 1-7

### Test on Stability in Supplying Trimethylindium

### Filling Amount; about 100 g

A supplying device was filled with trimethylindium supported on titanium sponge having a particle diameter of 0.84 to 4.75 mm in the same manner as in Example 1-6, except that the filling amount of trimethylindium supported on titanium sponge in Example 1-6 was changed to 211 g, and the test on the stability in supplying trimethylindium was carried out. As a result, the amount of trimethylindium supplied was about 0.40 g per hour, while the supply rate was stable up to 85% of a ratio of use.

### Example 1-8

### Test on Stability in Supplying Trimethylindium

### Filling Amount; about 25 g

A supplying device was filled with 71 g of trimethylindium supported on Heli Pack having a particle diameter of 0.84 to 4.76 mm in the same manner as in Example 1-1, except that the amount of argon gas introduced in Example 1-1 was changed to 600 ml per minute, and the test on the stability in supplying trimethylindium was carried out. As a result, the amount of trimethylindium supplied was about 0.80 g per minute, while the supply rate was stable up to 84% of a ratio of use.

### Example 1-9

### Test on Stability in Supplying Trimethylindium

### Filling Amount; about 25 g

A supplying device was filled with 75 g of trimethylindium supported on titanium sponge having a particle diameter of 0.84 to 4.75 mm in the same manner as in Example 1-4, except that the amount of argon gas introduced in Example 1-4 was changed to 600 ml per minute, and the test on the stability in supplying trimethylindium was carried out. As a result, the amount of trimethylindium supplied was about 0.80 g per minute, while the supply rate was stable up to 87% of a ratio of use.

### Example 1-10

### Test on Stability in Supplying Trimethylindium

### Filling Amount; about 25 g

A supplying device was filled with 53 g of trimethylindium supported on Dixon packing having a particle diameter of 0.84 to 4.76 mm in the same manner as in Example 1-5, except that the amount of argon gas introduced in Example 1-5 was changed to 600 ml per minute, and the test on the stability in supplying trimethylindium was carried out. As a result, the amount of trimethylindium supplied was about 0.80 g per minute, while the supply rate was stable up to 83% of a ratio of use.

### Example 1-11

### Test on Stability in Supplying Trimethylindium

### Filling Amount; about 50 g

A supplying device was filled with 152 g of trimethylindium supported on titanium sponge having a particle diameter of 0.84 to 4.75 mm in the same manner as in Example 1-6, except that the amount of argon gas introduced in Example 1-6 was changed to 600 ml per minute, and the test on the stability in supplying trimethylindium was carried out. As a result, the amount of trimethylindium supplied was about 0.80 g per hour, while the supply rate was stable up to 85% of a ratio of use.

### Example 1-12

### Test on Stability in Supplying Trimethylindium

### Filling Amount; about 50 g

A supplying device was filled with 151 g of trimethylindium supported on titanium sponge having a particle diameter of 0.84 to 4.76 mm in the same manner as in Example 1-3, except that the carrier of trimethylindium in Example 1-3 was changed to titanium sponge, and that the temperature in the thermostatic chamber in which the supplying device was installed was changed to 20° C., and the test on the stability in supplying trimethylindium was carried out. As a result, the amount of trimethylindium supplied was about 0.19 g per hour, while the supply rate was stable up to 85% of a ratio of use.

### Example 1-13

### Test on Stability in Supplying Trimethylindium

### Filing Amount; about 50 g

A supplying device was filled with 151 g of trimethylindium supported on titanium sponge having a particle diameter of 0.84 to 4.76 mm in the same manner as in Example 1-12, except that the amount of argon gas introduced in Example 1-12 was changed to 600 ml per minute, and the test on the stability in supplying trimethylindium was carried out. As a result, the amount of trimethylindium supplied was about 0.38 g per hour, while the supply rate was stable up to 85% of a ratio of use.

### Comparative Example 1

### Test on Stability in Supplying Trimethylindium

### Filling Amount; about 25 g

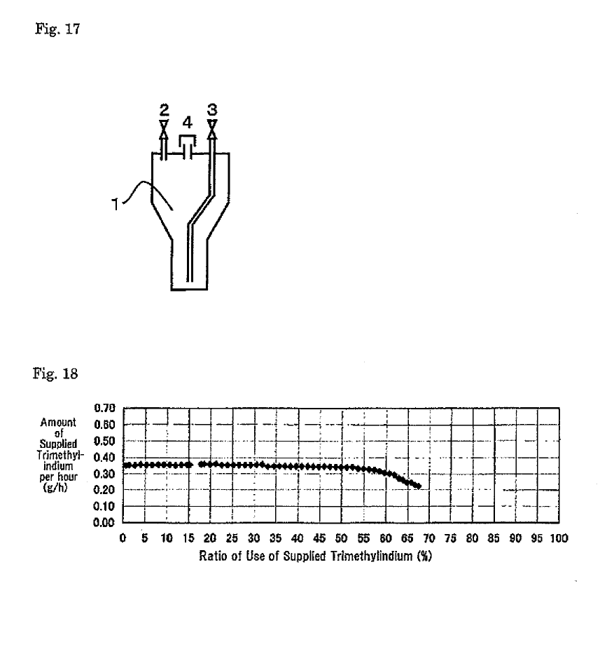

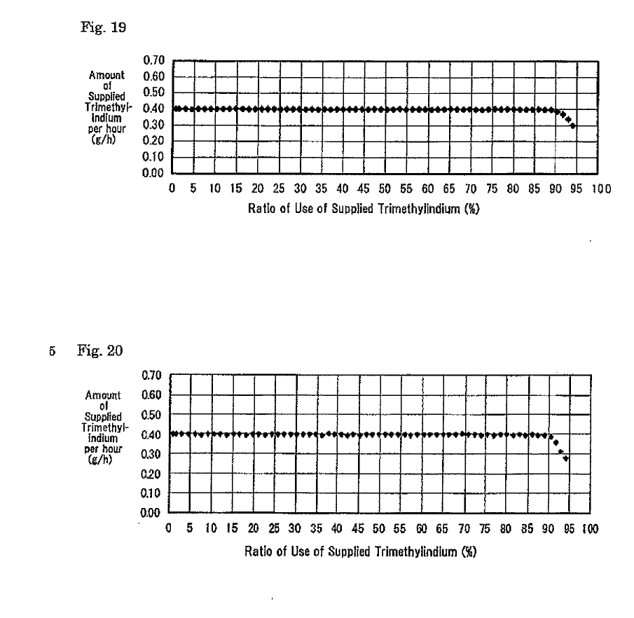

A stainless-steel supplying device was filled with 71 g of trimethylindium supported on Heli Pack having a particle diameter of 0.84 to 4.76 mm obtained in the method of Example 1-1 through filling port 4 in a nitrogen atmosphere. The supplying device was equipped with container 1 in a shape of narrow lower portion (inner diameter in the upper portion; 69 mm, inner diameter in the lower portion; 20 mm, height; 154 mm, inner volume; 300 ml) equipped with gas feed tube 2 and gas discharge tube 3 in the upper portion as shown in FIG. 17. In the inside of container 1, gas discharge tube 3 was extended to near the bottom wall of container 1.

This supplying device was installed in a thermostatic chamber kept at 30° C. and argon gas was allowed to flow at a flow rate of 300 ml per minute as a carrier gas from gas feed tube 2. As a result, the amount of trimethylindium supplied was about 0.36 g per hour, while the supply rate was stable only up to 55% of a ratio of use (FIG. 18).

### Comparative Example 2

### Test on Stability in Supplying Trimethylindium

### Filling Amount; about 25 g

A supplying device was filled with 77 g of trimethylindium supported on titanium sponge having a particle diameter of 0.84 to 4.76 mm in the same manner as in Comparative Example 1 through filling port 4 in a nitrogen atmosphere, except that the same titanium sponge as in Example 1-4 was used as a carrier for supporting trimethylindium in Comparative Example 1.

This supplying device was installed in a thermostatic chamber kept at 30° C. and argon gas was allowed to flow at a flow rate of 300 ml per minute from gas feed tube 2. As a result, the amount of trimethylindium supplied was about 0.39 g per hour, while the supply rate was stable only up to 56% of a ratio of use.

Main test conditions and test results in the above Examples 1-1 to 1-13 and Comparative Examples 1 and 2 are illustrated in Table 1.

TABLE 1

| | | | Amount | | | | | |
|---|---|---|---|---|---|---|---|---|
| | | | of | | | | | |
| | | | trimethyl- | | | | | |
| | Filling | | indium | | Inner | Temperature | | Ratio |
| | amount of | | supported | | volume of | in | Amount | of |
| | trimethyl- | | on | Supplying | supplying | thermostatic | of argon | stable |
| | indium*¹ | Carrier | carrier*² | device | device | chamber | gas | use*³ |
| Example | 25 g | Heli | 71 g | FIG. 1 | 62 ml | 30° C. | 300 ml/min | 85% |
| 1-1 | | Pack | | | | | | |
| Example | 25 g | Heli | 71 g | FIG. 3 | 261 ml | 30° C. | 300 ml/min | 80% |
| 1-2 | | Pack | | | | | | |
| Example | 25 g | Heli | 71 g | FIG. 2 | 169 ml | 30° C. | 300 ml/min | 82% |
| 1-3 | | Pack | | | | | | |
| Example | 25 g | Titanium | 75 g | FIG. 1 | 62 ml | 30° C. | 300 ml/min | 87% |
| 1-4 | | sponge | | | | | | |
| Example | 25 g | Dixon | 53 g | FIG. 1 | 62 ml | 30° C. | 300 ml/min | 84% |
| 1-5 | | packing | | | | | | |
| Example | 50 g | Titanium | 152 g | FIG. 3 | 261 ml | 30° C. | 300 ml/min | 85% |
| 1-6 | | sponge | | | | | | |
| Example | 100 g | Titanium | 211 g | FIG. 3 | 261 ml | 30° C. | 300 ml/min | 85% |
| 1-7 | | sponge | | | | | | |
| Example | 25 g | Heli | 71 g | FIG. 1 | 62 ml | 30° C. | 600 ml/min | 84% |
| 1-8 | | Pack | | | | | | |
| Example | 25 g | Titanium | 75 g | FIG. 1 | 62 ml | 30° C. | 600 ml/min | 87% |
| 1-9 | | sponge | | | | | | |
| Example | 25 g | Dixon | 53 g | FIG. 1 | 62 ml | 30° C. | 600 ml/min | 83% |
| 1-10 | | packing | | | | | | |
| Example | 50 g | Titanium | 152 g | FIG. 3 | 261 ml | 30° C. | 600 ml/min | 85% |
| 1-11 | | sponge | | | | | | |
| Example | 50 g | Titanium | 151 g | FIG. 2 | 169 ml | 20° C. | 300 ml/min | 85% |
| 1-12 | | sponge | | | | | | |
| Example | 50 g | Titanium | 151 g | FIG. 2 | 169 ml | 20° C. | 600 ml/min | 85% |
| 1-13 | | sponge | | | | | | |
| Comp. | 25 g | Heli | 71 g | FIG. 11 | 300 ml | 30° C. | 300 ml/min | 55% |
| Example 1 | | Pack | | | | | | |
| Comp. | 25 g | Titanium | 77 g | FIG. 11 | 300 ml | 30° C. | 300 ml/min | 56% |
| Example 2 | | sponge | | | | | | |

*¹indicates the amount of trimethylindium filled in a supplying device.
*²indicates the total amount of a carrier and trimethylindium filled in a supplying device.
*³indicates a ratio of use until the amount of stabilized trimethylindium supplied (g/hour) is lowered.

From Table 1, in each of Comparative Examples 1 and 2, a ratio of stable use of trimethylindium was 55 to 56%, whereas a ratio in each of Examples 1-1 to 1-13 reached 80% or higher which greatly improved a ratio of stable use of an organic metal compound as compared to the past.

2. Dispersed Introduction (1)

### Example 2-1

### Test on Stability in Supplying Trimethylindium

### Filling Amount; about 25 g

72 g of trimethylindium supported on Heli Pack having a particle diameter of 0.84 to 4.76 mm was obtained in the same manner as in Example 1-1. A stainless-steel supplying device having two containers 1, 1′ in a cylindrical shape as shown in FIG. 4 was filled with 72 g of the resulting trimethylindium supported on Heli Pack through filling port 4 in a nitrogen atmosphere. Container 1 equipped with gas feed tube 2 had an inner diameter of 37.1 mm, a height of 135 mm and an inner volume of 138 ml. Container 1′ equipped with gas discharge tube 3 had an inner diameter of 17.5 mm, a height of 135 mm and an inner volume of 31 ml. Communicating tube 5 was composed of a straight pipe having an inner diameter of 4.3 mm. Gas feed tube 2 inside container 1 was bent such that a carrier gas was introduced perpendicularly to the upper wall surface (introduction angle: 90°).

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.40 g per hour, while the supply rate was stable up to 89% of a ratio of use (FIG. 1-9).

### Example 2-2

### Test on Stability in Supplying Trimethylindium

### Filling Amount; about 25 g

A supplying device was filled with 77 g of trimethylindium supported on titanium sponge having a particle diameter of 0.84 to 4.76 mm in the same manner as in Example 2-1, except that titanium sponge (particle diameter: 0.84 to 2.00 mm (a product of Toho Titanium Co., Ltd.)) was used as a carrier for supporting trimethylindium in Example 2-1, and the test on the stability in supplying trimethylindium was carried out. As a result, the amount of trimethylindium supplied was about 0.40 g per minute, while the supply rate was stable up to 92% of a ratio of use.

### Example 2-3

### Test on Stability in Supplying Trimethylindium

### Filling Amount; about 25 g

A supplying device was filled with 51 g of trimethylindium supported on Dixon packing having a particle diameter of 0.84 to 4.76 mm in the same manner as in Example 2-1, except that Dixon packing (φ: 3.0 mm, height: 3.0 mm (a product of Okutani Wire Netting Mfg, Co., Ltd.)) was used as a carrier for supporting trimethylindium in Example 2-1, and the test on the stability in supplying trimethylindium was carried out. As a result, the amount of trimethylindium supplied was about 0.40 g per minute, while the supply rate was stable up to 89% of a ratio of use.

### Example 2-4

### Test on Stability in Supplying Trimethylindium

### Filling Amount; about 50 g

A supplying device was filled with 51 g of trimethylindium supported on Dixon packing having a particle diameter of 0.84 to 4.76 mm in the same manner as in Example 2-1, except that the filling amount of trimethylindium supported on Heli Pack in Example 2-1 was changed to 140 g, and the test on the stability in supplying trimethylindium was carried out. As a result, the amount of trimethylindium supplied was about 0.40 g per minute, while the supply rate was stable up to 89% of a ratio of use.

### Example 2-5

### Test on Stability in Supplying Trimethylindium

### Filling Amount; about 50 g

A supplying device was filled with 153 g of trimethylindium supported on titanium sponge having a particle diameter of 0.84 to 4.76 mm in the same manner as in Example 2-2, except that the filling amount of trimethylindium supported on titanium sponge in Example 2-2 was changed to 153 g, and the test on the stability in supplying trimethylindium was carried out. As a result, the amount of trimethylindium supplied was about 0.40 g per minute, while the supply rate was stable up to 92% of a ratio of use.

### Example 2-6

### Test on Stability in Supplying Trimethylindium

### Filling Amount; about 25 g

A supplying device was filled with 72 g of trimethylindium supported on Heli Pack having a particle diameter of 0.84 to 4.76 mm in the same manner as in Example 2-1, except that the amount of argon gas introduced in Example 2-1 was changed to 600 ml per minute, and the test on the stability in supplying trimethylindium was carried out. As a result, the amount of trimethylindium supplied was about 0.80 g per minute, while the supply rate was stable up to 87% of a ratio of use.

### Example 2-7

### Test on Stability in Supplying Trimethylindium

### Filling Amount; about 25 g

A supplying device was filled with 77 g of trimethylindium supported on titanium sponge having a particle diameter of 0.84 to 4.76 mm in the same manner as in Example 2-2, except that the amount of argon gas introduced in Example 2-2 was changed to 600 ml per minute, and the test on the stability in supplying trimethylindium was carried out. As a result, the amount of trimethylindium supplied was about 0.80 g per minute, while the supply rate was stable up to 92% of a ratio of use.

### Example 2-8

### Test on Stability in Supplying Trimethylindium

### Filling Amount; about 25 g

A supplying device was filled with 61 g of trimethylindium supported on Dixon packing having a particle diameter of 0.84 to 4.76 mm in the same manner as in Example 2-3, except that the amount of argon gas introduced in Example 2-3 was changed to 600 ml per minute, and the test on the stability in supplying trimethylindium was carried out. As a result, the amount of trimethylindium supplied was about 0.80 g per minute, while the supply rate was stable up to 88% of a ratio of use.

### Example 2-9

### Test on Stability in Supplying Trimethylindium

### Filling Amount; about 50 g

A supplying device was filled with 140 g of trimethylindium supported on Heli Pack having a particle diameter of 0.84 to 4.76 mm in the same manner as in Example 2-4, except that the amount of argon gas introduced in Example 2-4 was changed to 600 ml per minute, and the test on the stability in supplying trimethylindium was carried out. As a result the amount of trimethylindium supplied was about 0.80 g per minute, while the supply rate was stable up to 88% of a ratio of use.

### Example 2-10

### Test on Stability in Supplying Trimethylindium

### Filling Amount; about 50 g

A supplying device was filled with 163 g of trimethylindium supported on titanium sponge having a particle diameter of 0.84 to 4.76 mm in the same manner as in Example 2-5, except that the amount of argon gas introduced in Example 2-5 was changed to 600 ml per minute, and the test on the stability in supplying trimethylindium was carried out. As a result, the amount of trimethylindium supplied was about 0.80 g per minute, while the supply rate was stable up to 91% of a ratio of use.

Main test conditions and test results in Examples 1-1 to 1-10 are illustrated in Table 2.

TABLE 2

| | | | Amount | | | | | |
|---|---|---|---|---|---|---|---|---|
| | | | of | | | | | |
| | | | trimethyl- | | | | | |
| | Filling | | indium | | Inner | Temperature | | Ratio |
| | amount of | | supported | | volume of | in | Amount | of |
| | trimethyl- | | on | Supplying | supplying | thermostatic | of argon | stable |
| | indium*¹ | Carrier | carrier*² | device | device | chamber | gas | use*³ |
| Example | 25 g | Heli | 72 g | FIG. 4 | 169 ml | 30° C. | 300 ml/min | 89% |
| 2-1 | | Pack | | | | | | |
| Example | 25 g | Titanium | 77 g | FIG. 4 | 169 ml | 30° C. | 300 ml/min | 92% |
| 2-2 | | sponge | | | | | | |
| Example | 25 g | Dixon | 51 g | FIG. 4 | 169 ml | 30° C. | 300 ml/min | 89% |
| 2-3 | | packing | | | | | | |
| Example | 50 g | Heli | 140 g | FIG. 4 | 169 ml | 30° C. | 300 ml/min | 89% |
| 2-4 | | Pack | | | | | | |
| Example | 50 g | Titanium | 153 g | FIG. 4 | 169 ml | 30° C. | 300 ml/min | 92% |
| 2-5 | | sponge | | | | | | |
| Example | 25 g | Heli | 72 g | FIG. 4 | 169 ml | 30° C. | 600 ml/min | 87% |
| 2-6 | | Pack | | | | | | |
| Example | 25 g | Titanium | 77 g | FIG. 4 | 169 ml | 30° C. | 600 ml/min | 92% |
| 2-7 | | sponge | | | | | | |
| Example | 25 g | Dixon | 51 g | FIG. 4 | 169 ml | 30° C. | 600 ml/min | 88% |
| 2-8 | | packing | | | | | | |
| Example | 50 g | Heli | 140 g | FIG. 4 | 169 ml | 30° C. | 600 ml/min | 88% |
| 2-9 | | Pack | | | | | | |
| Example | 50 g | Titanium | 153 g | FIG. 4 | 169 ml | 30° C. | 600 ml/min | 91% |
| 2-10 | | sponge | | | | | | |

*¹indicates the amount of trimethylindium filled in a supplying device.
*²indicates the total amount of a carrier and trimethylindium filled in a supplying device.
*³indicates a ratio of use until the amount of stabilized trimethylindium supplied (g/hour) is lowered.

From Table 2, it is found that a carrier gas was allowed to collide against the upper wall surface of the container (1) so that a ratio of stable use could be further improved in each of Examples 2-1 to 2-10.

3. Dispersed Introduction (2)

### Example 3-1

### Test on Stability in Supplying Trimethylindium

### Filling Amount; about 25 g

71 g of trimethylindium supported on Heli Pack having a particle diameter of 0.84 to 4.76 mm was obtained in the same manner as in Example 1-1. A stainless-steel supplying device having two containers 1, 1′ in a cylindrical shape as shown in FIG. 5 was filled with 71 g of the resulting trimethylindium supported on Heli Pack through filling port 4 in a nitrogen atmosphere. Container 1 equipped with gas feed tube 2 had an inner diameter of 37.1 mm, a height of 135 mm and an inner volume of 138 ml. Container 1′ equipped with gas discharge tube 3 had an inner diameter of 17.5 mm, a height of 135 mm and an inner volume of 31 ml. Communicating tube 5 was composed of a straight pipe having an inner diameter of 4.8 mm. Inside container 1, disperser 6 composed of a cone type baffle plate having a recessed part in the center was positioned at a lower part of gas feed tube 2.

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.40 g per hour, while the supply rate was stable up to 89% of a ratio of use (FIG. 20).

### Example 3-2

### Test on Stability in Supplying Trimethylindium

### Filling Amount; about 25 g

A supplying device was filled with 52 g of trimethylindium supported on Dixon packing having a particle diameter of 0.84 to 4.76 mm in the same manner as in Example 3-1, except that Dixon packing (φ: 3.0 mm, height: 3.0 mm (a product of Okutani Wire Netting Mfg, Co., Ltd.)) was used as a carrier for supporting trimethylindium in Example 3-1, and the test on the stability in supplying trimethylindium was carried out. As a result, the amount of trimethylindium supplied was about 0.40 g per minute, while the supply rate was stable up to 89% of a ratio of use.

### Example 3-3

### Test on Stability in Supplying Trimethylindium

### Filling Amount; about 25 g

A supplying device was filled with 75 g of trimethylindium supported on titanium sponge having a particle diameter of 0.84 to 4.76 mm in the same manner as in Example 3-1, except that titanium sponge (particle diameter: 0.84 to 2.00 mm (a product of Toho Titanium Co., Ltd.)) was used as a carrier for supporting trimethylindium in Example 3-1, and the test on the stability in supplying trimethylindium was carried out. As a result, the amount of trimethylindium supplied was about 0.40 g per minute, while the supply rate was stable up to 93% of a ratio of use.

### Example 3-4

### Test on Stability in Supplying Trimethylindium

### Filling Amount; about 25 g

71 of trimethylindium supported on Heli Pack having a particle diameter of 0.84 to 4.76 mm was obtained in the same manner as in Example 1-1. A stainless-steel supplying device having two containers 1, 1′ in a cylindrical shape as shown in FIG. 6 was filled with 71 g of the resulting trimethylindium supported on Heli Pack through filling port 4 in a nitrogen atmosphere. Containers 1, 1′ and communicating tube 5 were the same as those used in Example 3-1. Inside container 1, disperser 6 composed of a perforated pipe was integrated at gas feed tube 2.

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.40 g per hour, while the supply rate was stable up to 89% of a ratio of use.

### Example 3-5

### Test on Stability in Supplying Trimethylindium

### Filling Amount; about 25 g

71 of trimethylindium supported on Heli Pack having a particle diameter of 0.84 to 4.76 mm was obtained in the same manner as in Example 1-1. A stainless-steel supplying device having two containers 1, 1′ in a cylindrical shape as shown in FIG. 7 was filled with 71 g of the resulting trimethylindium supported on Heli Pack through filling port 4 in a nitrogen atmosphere. Containers 1, 1 and communicating tube 5 were the same as those used in Example 3-1. Inside container 1, disperser 6 composed of a flat plate was positioned at a lower part of gas feed tube 2.

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.40 g per hour, while the supply rate was stable up to 89% of a ratio of use.

### Example 3-6

### Test on Stability in Supplying Trimethylindium

### Filling Amount; about 25 g

71 g of trimethylindium supported on Heli Pack having a particle diameter of 0.84 to 4.76 mm was obtained in the same manner as in Example 1-1. A stainless-steel supplying device having two containers 1, 1′ in a cylindrical shape as shown in FIG. 8 was filled with 71 g of the resulting trimethylindium supported on Heli Pack through filling port 4 in a nitrogen atmosphere Containers 1, 1′ and communicating tube 6 were the same as those used in Example 3-1. Inside container 1, disperser 6 composed of a sintered metal filter was positioned at a lower part of gas feed tube 2.

This supplying device was installed in a thermostatic chamber kept at 30° C. and argon gas was introduced into container 1 at a flow rate of 300 ml per minute as a carrier gas from gas feed tube 2. As a result, the amount of supplied trimethylindium obtained from gas discharge tube 3 of container 1′ was about 0.40 g per hour, while the supply rate was stable up to 88% of a ratio of use.

### Example 3-7

### Test on Stability in Supplying Trimethylindium

### Filling Amount; about 25 g

A supplying device was filled with 75 g of trimethylindium supported on titanium sponge having a particle diameter of 0.84 to 4.76 mm in the same manner as in Example 3-3, except that a supplying device having a different size of containers 1, 1′ in Example 3-3 was used, and the test on the stability in supplying trimethylindium was carried out. The size of container 1 was an inner diameter of 55 mm, a height of 135 mm and an inner volume of 802 ml, while the size of container 1 was an inner diameter of 23 mm, a height of 135 mm, and an inner volume of 53 ml. As a result of the test on the stability in supplying trimethylindium, the amount of trimethylindium supplied was about 0.40 g per minute, while the supply rate was stable up to 92% of a ratio of use.

### Example 3-8

### Test on Stability in Supplying Trimethylindium

### Filling Amount; about 50 g

A supplying device was filled with 153 g of trimethylindium supported on titanium sponge having a particle diameter of 0.84 to 4.76 mm in the same manner as in Example 3-3, except that the filling amount of trimethylindium supported on titanium sponge in Example 3-3 was changed to 150 g, and the test on the stability in supplying trimethylindium was carried out. As a result, the amount of trimethylindium supplied was about 0.40 g per minute, while the supply rate was stable up to 93% of a ratio of use.

### Examples 3-9 to 3-22

A supplying device was filled with trimethylindium supported on a carrier having a particle diameter of 0.84 to 4.76 mm obtained in the same manner as in Example 3-1 in a nitrogen atmosphere, except that the filling amount of trimethylindium, a carrier, a configuration of disperser 6 in the supplying device, a temperature in a thermostatic chamber and the amount of argon gas introduced were changed, and the test on the stability in supplying trimethylindium was carried out.

Main test conditions and test results in Examples 3-1 to 3-22 are illustrated in Table 3.

TABLE 3

| | | | Amount | | | | | |
|---|---|---|---|---|---|---|---|---|
| | | | of | | | | | |
| | | | trimethyl- | | | | | |
| | Filling | | indium | | Inner | Temperature | | Ratio |
| | amount of | | supported | | volume of | in | Amount | of |
| | trimethyl- | | on | Supplying | supplying | thermostatic | of argon | stable |
| | indium*¹ | Carrier | carrier*² | device | device | chamber | gas | use*³ |
| Example | 25 g | Heli | 71 g | FIG. 5 | 169 ml | 30° C. | 300 ml/min | 89% |
| 3-1 | | Pack | | | | | | |
| Example | 25 g | Dixon | 52 g | FIG. 5 | 169 ml | 30° C. | 300 ml/min | 89% |
| 3-2 | | packing | | | | | | |
| Example | 25 g | Titanium | 75 g | FIG. 5 | 169 ml | 30° C. | 300 ml/min | 93% |
| 3-3 | | sponge | | | | | | |
| Example | 25 g | Heli | 71 g | FIG. 6 | 169 ml | 30° C. | 300 ml/min | 89% |
| 3-4 | | Pack | | | | | | |
| Example | 25 g | Heli | 71 g | FIG. 7 | 169 ml | 30° C. | 300 ml/min | 89% |
| 3-5 | | Pack | | | | | | |
| Example | 25 g | Heli | 71 g | FIG. 8 | 169 ml | 30° C. | 300 ml/min | 88% |
| 3-6 | | Pack | | | | | | |
| Example | 25 g | Titanium | 75 g | FIG. 5 | 355 ml | 30° C. | 300 ml/min | 92% |
| 3-7 | | sponge | | | | | | |
| Example | 50 g | Titanium | 150 g | FIG. 5 | 169 ml | 30° C. | 300 ml/min | 93% |
| 3-8 | | sponge | | | | | | |
| Example | 25 g | Heli | 71 g | FIG. 5 | 169 ml | 30° C. | 600 ml/min | 89% |
| 3-9 | | Pack | | | | | | |
| Example | 25 g | Titanium | 75 g | FIG. 5 | 169 ml | 30° C. | 600 ml/min | 93% |
| 3-10 | | sponge | | | | | | |
| Example | 25 g | Heli | 71 g | FIG. 6 | 169 ml | 30° C. | 600 ml/min | 88% |
| 3-11 | | Pack | | | | | | |
| Example | 25 g | Titanium | 75 g | FIG. 5 | 355 ml | 30° C. | 600 ml/min | 91% |
| 3-12 | | sponge | | | | | | |
| Example | 50 g | Titanium | 150 g | FIG. 5 | 169 ml | 30° C. | 600 ml/min | 91% |
| 3-13 | | sponge | | | | | | |
| Example | 50 g | Titanium | 150 g | FIG. 5 | 330 ml | 20° C. | 300 ml/min | 97% |
| 3-14 | | sponge | | | | | | |
| Example | 50 g | Titanium | 150 g | FIG. 5 | 330 ml | 20° C. | 600 ml/min | 97% |
| 3-15 | | sponge | | | | | | |
| Example | 50 g | Titanium | 150 g | FIG. 5 | 330 ml | 20° C. | 1000 ml/min | 95% |
| 3-16 | | sponge | | | | | | |
| Example | 100 g | Titanium | 298 g | FIG. 5 | 330 ml | 20° C. | 300 ml/min | 97% |
| 3-17 | | sponge | | | | | | |
| Example | 100 g | Titanium | 298 g | FIG. 5 | 330 ml | 20° C. | 600 ml/min | 97% |
| 3-18 | | sponge | | | | | | |
| Example | 100 g | Titanium | 298 g | FIG. 5 | 330 ml | 20° C. | 1000 ml/min | 95% |
| 3-19 | | sponge | | | | | | |
| Example | 300 g | Titanium | 893 g | FIG. 5 | 750 ml | 20° C. | 300 ml/min | 95% |
| 3-20 | | sponge | | | | | | |
| Example | 300 g | Titanium | 893 g | FIG. 5 | 750 ml | 20° C. | 600 ml/min | 95% |
| 3-21 | | sponge | | | | | | |
| Example | 300 g | Titanium | 893 g | FIG. 5 | 750 ml | 20° C. | 1000 ml/min | 93% |
| 3-22 | | sponge | | | | | | |

*¹indicates the amount of trimethylindium filled in a supplying device.
*²indicates the total amount of a carrier and trimethylindium filled in a supplying device.
*³indicates a ratio of use until the amount of stabilized trimethylindium supplied (g/hour) is lowered.

1. A device for supplying an organic metal compound comprising:
a first and a second columnar containers filled with an organic metal compound which is in a solid state at room temperature; and
a connecting member for connecting the insides of the first and second containers with each other at the lower ends;
wherein the upper portion of the first container is equipped with an inlet for a carrier gas and the upper portion of the second container is equipped with an outlet for the carrier gas containing the organic metal compound.

2. The supplying device according to claim 1, wherein the inlet is equipped with a gas feed tube mounted on the first container such that the carrier gas introduced into the first container is allowed to collide against the upper w all surface of the first container.

3. The supplying device according to claim 2, wherein the tip end of the gas feed tube is directed upward in the inside of the first container.

4. The supplying device according to claim 1, wherein the inlet is equipped with a disperser for dispersing the carrier gas introduced into the first container.

5. The supplying device according to claim 4, wherein the disperser has a baffle plate for dispersing the carrier gas introduced into the first container by allowing the carrier gas to collide therewith.

6. The supplying device according to claim 4, wherein the disperser has a perforated pipe positioned in the inside of the first container.

7. The supplying device according to claim 4, wherein the disperser has a filter positioned in the inside of the first container.

8. The supplying de vice according to claim 1, wherein the first container and the second container are positioned such that they are spaced from each other.

9. The supplying device according to claim 1, wherein the connecting member has a communicating tube for connecting the first container and the second container.

10. The supplying device according to claim 9, wherein the communicating tube is composed of a single straight pipe or a plurality of straight pipes.
